(19) United States
(12) Patent Application Publication
(10) Pub. No.: US 2006/0275981 A1
(43) Pub. Date: Dec. 7, 2006

(54) Memory and method for fabricating it

(75) Inventors: Alejandro Avellan, Dresden (DE); Matthias Goldbach, Dresden (DE); Thomas Hecht, Dresden (DE); Stefan Jakschik, Kessel-Lo (Leuven) (BE); Andreas Orth, Dresden (DE); Uwe Schroder, Dresden (DE); Michael Stadtmueller, Dresden (DE); Olaf Storbeck, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/442,602

(22) Filed: May 30, 2006

(30) Foreign Application Priority Data
May 31, 2005 (DE) 10 2005 024 855.1

(51) Int. Cl. H01L 21/8242; H01L 29/94

(52) U.S. Cl. 438/253; 257/296

(57) ABSTRACT

Memory and method for fabricating it A memory formed as an integrated circuit in a semiconductor substrate and having storage capacitors and switching transistors. The storage capacitors are formed in the semiconductor substrate in a trench and have an outer electrode layer, which is formed around the trench, a dielectric intermediate layer, which is embodied on the trench wall, and an inner electrode layer, with which the trench is essentially filled, and the switching transistors are formed in the semiconductor substrate in a surface region and have a first source/drain doping region, a second source/drain doping region and an intervening channel, which is separated from a gate electrode by an insulator layer.

### CLAIM FOR PRIORITY

This application claims the benefit of priority to German Application No. 10 2005 024 855.1, filed in the German language on May 31, 2005, the contents of which are hereby incorporated by reference.

### TECHNICAL FIELD OF THE INVENTION

The invention relates to a memory and method for fabricating a memory which is formed as an integrated circuit in a semiconductor substrate.

### BACKGROUND OF THE INVENTION

Semiconductor memories, principally DRAMs, are generally realized as a memory cell matrix on a semiconductor wafer. In this case, the memory cells comprise a storage capacitor and a selection transistor. During a reading or writing operation, the storage capacitor is charged or discharged with an electrical charge corresponding to the respective data unit, via the selection transistor. For this purpose, the selection transistor is addressed via a bit or word line with the aid of a peripheral logic having switching transistors.

A significant main focus in the technological development of semiconductor memories, in particular DRAMs, is the storage capacitor. In order to provide for a sufficient storage capacitance in conjunction with a small cross-sectional area, the storage capacitors are therefore realized three-dimensionally in the form of trench capacitors. In the case of such trench capacitors, a trench is etched into the semiconductor substrate, the trench being filled with a dielectric intermediate layer and a first storage electrode, a doped region of the semiconductor substrate around the trench serving as a second storage electrode. The selection transistor of the memory cell is usually formed as a planar field effect transistor alongside the trench capacitor on the semiconductor surface, one source/drain electrode being connected to the inner electrode of the trench capacitor.

On account of the still increasing miniaturization of the memory cells, even in the case of trench capacitors additional possibilities are being sought for simultaneously reducing the area requirement and increasing the capacitor capacitance. One possibility for increasing the capacitance in the case of trench capacitors is to use very thin insulator layers having a high dielectric constant as a dielectric intermediate layer between the capacitor electrodes. Material combinations comprising thin silicon dioxide and silicon nitride layers are conventionally used as storage dielectric in the case of trench capacitors, the inner electrode of the trench capacitor generally comprising doped polysilicon.

With trench capacitors constructed in this way, it becomes more and more difficult, however, in the context of the cell area that constantly decreases from technology generation to technology generation, to provide for a sufficient storage capacitance. For sub-100 nm structures, therefore, consideration is being given to a material modification in the case of the storage dielectric. The aim is for the materials that are conventionally used for the dielectric intermediate layer in trench capacitors to be replaced by materials which are distinguished by a higher dielectric constant and thus enable the area-specific storage capacitance to be increased. Such materials, what are known as high-k dielectrics, are e.g. hafnium oxide, zirconium oxide or oxides of the lanthanide series.

However, these high-k dielectrics are generally thermally stable only in a temperature range below 800° C. and are therefore suitable only to a very limited extent for replacing the conventional dielectric intermediate layers in trench capacitors, since temperatures above 1000° C. are often required when forming memory cells in the context of silicon planar technology, particularly when activating dopings of the switching transistors. Although high-k dielectrics having a higher thermal stability are also known, these high-temperature high-k dielectrics can only be integrated with very great difficulty into the standard process for fabricating trench capacitors in the context of silicon planar technology and, in particular, can be formed as extremely thin layers only with very great difficulty.

### SUMMARY OF THE INVENTION

The invention relates to a method for fabricating a memory which is formed as an integrated circuit in a semiconductor substrate and comprises storage capacitors and switching transistors, and to a memory fabricated in accordance with this method, in particular a dynamic random access memory (DRAM).

In accordance with a first embodiment of the invention, there is a method for fabricating a memory which is formed as an integrated circuit in a semiconductor substrate and comprises storage capacitors and switching transistors comprises the following: the storage capacitors are formed in the semiconductor substrate in each case in a trench and have an outer electrode layer, which is formed around the trench, a dielectric intermediate layer, which is embodied on the trench wall and comprises a high-k dielectric that is unstable at high temperatures of above 800° C., and an inner electrode layer, with which the trench is essentially filled; the switching transistors are formed in the semiconductor substrate in each case in a surface region and have a first source/drain doping region, a second source/drain doping region and an intervening channel, which is separated from a gate electrode by an insulator layer; the dielectric intermediate layer of the storage capacitors is embodied in a manner spaced apart from the surface of the semiconductor substrate at least by a magnitude corresponding to the depth to which the source/drain doping regions of the switching transistors extend in the semiconductor substrate; and a short-time heat-treatment method is used for the thermal activation of the dopants in the source/drain doping zones of the switching transistors at temperatures of above 1000° C., during which method the thermal energy is coupled in from the wafer surface for a few microseconds to milliseconds.

In accordance with a second embodiment of the invention, there is a method for fabricating a memory which is formed as an integrated circuit in a semiconductor substrate and comprises storage capacitors and switching transistors comprises the following: a dielectric intermediate layer of the trench capacitors is formed with a low-temperature high-k dielectric, the dielectric intermediate layer of the storage capacitors being embodied in a manner spaced apart from the surface of the semiconductor substrate at least by a magnitude corresponding to the depth to which the source/drain doping regions of the field effect transistors extend; and one of the methods laser annealing, flash annealing and SPER annealing is used for the thermal activation of the dopants in the source/drain doping zones of the switching transistors in the semiconductor substrate.

In accordance with a third embodiment of the invention, the memory which is formed as an integrated circuit in a semiconductor substrate comprises storage capacitors and switching transistors. The storage capacitors in the semiconductor substrate are formed in each case in a trench and have an outer electrode layer, which is formed around the trench, a dielectric intermediate layer, which is embodied on the trench wall, and an inner electrode layer, with which the trench is essentially filled. The switching transistors in the semiconductor substrate are formed in each case in a surface region and have a first source/drain doping region, a second source/drain doping region and an intervening channel, which is separated from a gate electrode by an insulator layer. The dielectric intermediate layer of the storage capacitors comprises a low-temperature high-k dielectric, the source/drain doping regions of the switching transistors extending to a depth of approximately 200 nm from the surface of the semiconductor substrate, and the dielectric intermediate layer of the storage capacitors being spaced apart from the surface of the semiconductor substrate by at least 200 nm.

### BRIEF DESCRIPTION OF THE DRAWINGS

These and other objects and features of the present invention will become clear from the following description taken in conjunction with the accompanying drawings in which:

FIG. 1 shows a circuit diagram of a dynamic memory cell in a DRAM memory.

FIGS. 2 to 7 show an embodiment of a method according to the invention for fabricating a DRAM memory according to the invention.

### DETAILED DESCRIPTION OF THE INVENTION

According to the invention, in the case of a memory which is formed as an integrated circuit in a semiconductor substrate and comprises storage capacitors and switching transistors, the storage capacitor being formed in the semiconductor substrate as a trench capacitor and the switching transistors being formed as field effect transistors, the dielectric intermediate layer of the trench capacitors is formed with a high-k dielectric that is unstable at a high temperature, in particular a temperature above 800° C., the dielectric intermediate layer of the storage capacitors being embodied in a manner spaced apart from the surface of the semiconductor substrate at least by a magnitude corresponding to the depth to which the source/drain doping regions of the field effect transistors extend.

The buried embodiment of the dielectric intermediate layer of the trench capacitors affords the possibility of fabricating the dielectric intermediate layer on a low-temperature high-k dielectric which is distinguished by a high dielectric constant and hence an increased storage capacitance for trench capacitors. Although the low-temperature high-k dielectric is only stable in a temperature range below 800° C., that is to say a temperature range far below the temperature of above 1000° C. required for the activation of the dopants in the source/drain doping regions of the switching transistors, the buried design of the dielectric intermediate layer in such a way that the intermediate layer is arranged deeper than the doping regions of the switching transistors makes it possible to ensure that the high temperatures for activating the dopants in the doping zones do not damage the low-temperature high-k dielectric layer situated deeper.

In this case, it is preferred for the dielectric intermediate layer of the trench capacitors to be formed in a manner spaced apart from the surface of the semiconductor substrate by at least 200 nm.

Furthermore, it is preferred in this case to implement the dopants of the source/drain regions of the switching transistors in the semiconductor substrate with the aid of laser annealing, flash annealing or SPER annealing. With these heating processes, it is possible to heat only the surface region of the semiconductor substrate in which the dopants are arranged to the temperature of at least 1000° C. required for the activation of the dopants.

The invention is explained on the basis of a process sequence for forming a DRAM memory. In this case, the individual structures of the DRAM memory are preferably formed with the aid of silicon planar technology, which comprises a sequence of individual processes that in each case act over the whole area of the surface of a silicon semiconductor wafer, a local alteration of the silicon substrate being carried out in a targeted manner by means of suitable masking layers. During the DRAM memory fabrication, a multiplicity of dynamic memory cells are formed simultaneously in this case.

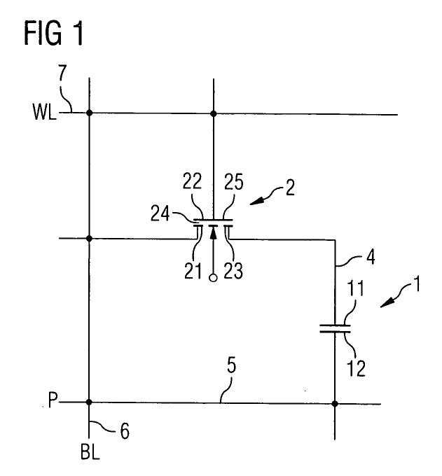

FIG. 1 shows a circuit diagram of a one-transistor memory cell such as is predominantly used in DRAM memories. The one-transistor memory cell comprises a storage capacitor 1 and a selection transistor 2. In this case, the selection transistor 2 is formed as a field effect transistor and has a first source/drain electrode 21 and a second source/drain electrode 23, between which an active region 22 is arranged. Arranged above the active region are a gate insulator layer 24 and gate electrode 25, which act like a plate capacitor which can influence the charge density in the active region 22 in order to form or block a current-conducting channel between the first source/drain electrode 21 and the second source/drain electrode 23.

The second source/drain electrode 23 of the selection transistor 2 is connected to a first electrode 11 of the storage capacitor 1 via a connecting line 4. A second electrode 12 of the storage capacitor 1 is in turn connected to a capacitor plate 5, which is preferably common to all the storage capacitors of the DRAM memory cell arrangement. The first electrode 21 of the selection transistor 2 is furthermore connected to a bit line 6 in order that the information stored in the storage capacitor 1 in the form of charges can be read in and out. In this case, the reading-in or reading-out operation is controlled via a word line 7, which is at the same time the gate electrode 25 of the selection transistor 2, in order, by applying a voltage, to produce a current-conducting channel in the active region 22 between the first source/drain electrode 21 and the second source/drain electrode 23.

In many cases trench capacitors are used as storage capacitors in dynamic memory cells since a significant reduction of the memory cell area can be achieved by means of the three-dimensional structure. With increasing miniaturization of the memory cells, given a scaling size of less than 100 nm, additional measures are necessary, however, in order to be able to fulfill the three basic requirements made of a dynamic memory cell in a DRAM memory, namely a sufficiently large storage capacitance of approximately 25 to 40 fF, which is necessary for reliable detection of the charge stored in the storage capacitor, a packing-dense and structure-friendly cell layout, which provides for a minimum chip area and thus for reduced costs, and also a high performance of the selection transistor, in particular a high read-in and read-out current with an at the same time low reverse current.

In order to provide for a sufficient storage capacitance in the case of a reduced trench capacitor cross section, according to the invention the dielectric intermediate layer made of silicon dioxide and/or silicon nitride layers that is conventionally used between the two capacitor electrodes in the trench capacitors is replaced by a high-k dielectric having a higher dielectric constant. This procedure makes it possible to reduce the trench capacitor dimensioning and at the same time to maintain the storage capacitance required for reliable detection.

Preferred materials in this case are binary oxides, such as e.g. tantalum oxide (Ta₂O₅) having a dielectric constant of 25 and a temperature stability up to 800° C. The use of aluminum oxide (Al₂O₃) having a dielectric constant of 10 and a temperature stability up to 830° C. is also advantageous. Moreover, hafnium oxide (HfO₂) having a dielectric constant of 50 to 60, and zirconium oxide (ZrO₂) having a dielectric constant of 11 to 25 are also suitable for use as a high-k dielectric. Lanthanum oxide (L₂O₃) having a dielectric constant of 20 to 25, and yttrium oxide (Y₂O₃) having a dielectric constant of 11 to 12 may also be used. These materials are stable in the temperature range up to 800° C.

Furthermore, aluminum oxide compounds are taken into consideration as high-k dielectrics. In particular compounds with hafnium, zirconium and lanthanum, for example Hf—Al—O, Zr—Al—O or La—Al—O, are suitable for this. Furthermore, high-k dielectrics may also be produced from silicate compounds, such as e.g. Hf—Si-0, Zr—Si—O, La—Si—O or Y—Si—O. The aluminum and silicate compounds are distinguished by a dielectric constant of above 14 with a temperature stability up to 900°.

Moreover, further individual or mixed oxides or nitrides of the fourth or fifth secondary group and of the third and fourth main groups are suitable as high-k dielectrics, but the high-k dielectrics, particularly when they are suitable for use in the context of silicon planar technology for application as a dielectric intermediate layer in the trench capacitor, have a temperature stability of generally not more than 800° C.

However, in the standard process sequences for fabricating memories in the context of silicon planar technology, temperatures of above 1000° C. generally occur after the introduction of the dielectric intermediate layer. This applies in particular to the required heating for activating the dopants in the source/drain doping zones of the field effect transistors which are used both as selection transistors in the memory cells but also as drive transistors in the peripheral logic region of the DRAM memory.

In order to prevent these high temperatures of above 1000° C. from damaging the low-temperature high-k dielectric layer of the trench capacitors, according to the invention the low-temperature high-k dielectric layer is embodied in a manner spaced apart from the surface of the semiconductor substrate at least by a magnitude corresponding to the depth to which the first source/drain doping region and the second source/doping drain region of the field effect transistors extend in the semiconductor substrate. In the case of shallow source/drain doping zones such as are generally embodied in planar field effect transistors used as switching transistors in DRAM memories, the doping zones extend to a depth of approximately 200 nm, so that the dielectric intermediate layer of the trench capacitors is embodied in a manner spaced apart from the surface of the semiconductor substrate at least by this magnitude.

At the same time, the semiconductor substrate heating processes which are performed in the context of the fabrication of the DRAM memory after the introduction of the low-temperature high-k dielectric as dielectric intermediate layer in the trench capacitors are carried out in such a way that only the surface region of the semiconductor substrate above the buried low-temperature high-k dielectric layers is heated. This applies in particular to the thermal activation of the dopants in the source/drain doping zones of the switching transistors.

According to the invention, short-time heat treatment methods in which the thermal energy is coupled in for a few microseconds to milliseconds from the wafer surface are used in this case as surface heating methods. It is preferred in this case to carry out short-time heating by means of laser beams (laser annealing), by means of a flash high-energy lamp (flash assisted rapid thermal processing) or by means of SPER technology (solid phase epitaxial regrowth), in which a recrystallization of the layer is achieved. These heating methods ensure that the high temperatures of above 1000° C. for activating the dopants in the source/drain doping zones occur only in the doping zone itself, that is to say at the semiconductor surface above the low-temperature high-k dielectric layers.

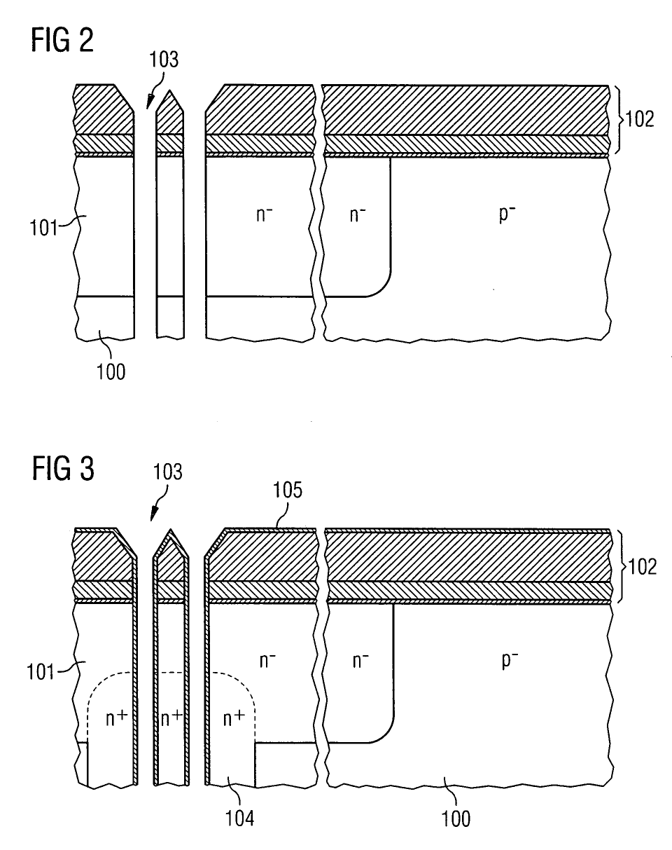

FIGS. 2 to 7 show a process sequence according to the invention for fabricating a DRAM memory in silicon planar technology, a cross section through a silicon wafer being shown schematically in each case. A memory cell region and a peripheral logic region are provided here on the silicon wafer. The memory cells of the DRAM memory are composed of a planar field effect transistor and a trench capacitor. The peripheral logic region contains various components, the switching transistors being fabricated in CMOS technology.

The starting material is a p⁻-doped silicon substrate 100, in which an n⁻-doped memory cell region 101 is defined by means of a lithography step and a subsequent ion implantation. A multilayer masking layer 102 for trench etching is then applied on the semiconductor substrate and the storage capacitor region is defined with the aid of a further lithography step. An etching mask is then produced from the masking layer 102 with the aid of an anisotropic etch. An anistropic silicon etch is subsequently carried out in order to form trenches 103 for the storage capacitors which have a depth of 3 to 10 μm. FIG. 2 shows a cross section through the silicon wafer after embodiment of the trenches 103.

In a next process sequence, the buried outer capacitor electrode is then formed by producing an n⁺-doped buried plate electrode 104. After embodiment of the buried plate electrode 104, a dielectric intermediate layer 105 is then produced in the trenches 103, the low-temperature high-k dielectric specified above being used as material combination for the dielectric intermediate layer. A cross section through the silicon wafer after the deposition of the low-temperature high-k dielectric of the storage capacitors is shown in FIG. 3.

In a further process sequence, the inner capacitor electrode is then formed. In this case, n⁺-doped polysilicon or else a metallic filling material may be used as material for the inner capacitor electrode. Noble metal but also conductive metal oxide and nitride compounds such as TiN or RuO may be used in this case. The metallic layer has a lower resistance compared with the n⁺-doped polysilicon.

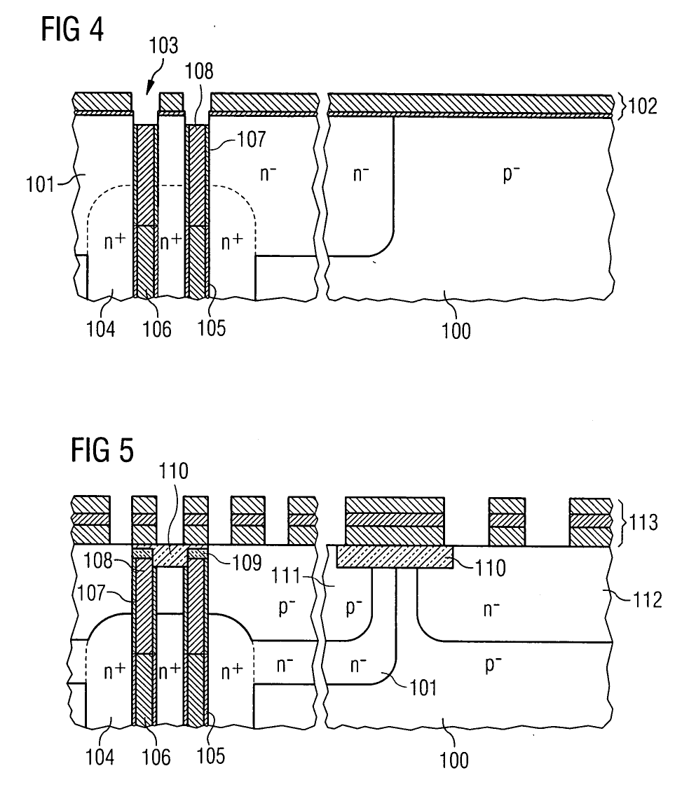

After the filling of the trenches 103, the electrode layer 106 is etched back by 200 to 2000 nm below the surface of the silicon substrate 100 and the low-temperature high-k dielectric layer is removed on the uncovered walls of the trenches 103. A silicon dioxide layer 107 is then produced as a collar on the uncovered trench walls and the trench is filled with n⁺-doped polysilicon 108. A cross section through the silicon wafer after the filling of the trenches with n⁺-doped polysilicon 108 is illustrated in FIG. 4.

A further process sequence then involves producing buried strap contacts 109 for the connection of the selection transistors that are formed later and are arranged in planar fashion alongside the trench. Afterward, insulation regions 110 are then defined with the aid of a lithographic step and after these regions have been etched free they are filled with silicon dioxide, preferably with the aid of the TEOS method in a temperature range of below 800° C.

The selection transistors of the memory cells and also the switching transistors—fabricated in CMOS technology—of the peripheral logic region are then fabricated in a further process sequence. For this purpose, in a first step with the aid of a lithography process and an ion implantation, the n-channel transistor regions are defined by producing a p⁻-doped well 111 and the p-channel transistor regions are defined by producing an n⁻-doped well 112. The multilayer gate electrode tracks 113 of the transistors are then produced with the aid of a further lithography process. FIG. 5 shows a cross section through the silicon wafer after the formation of the gate electrode tracks 113.

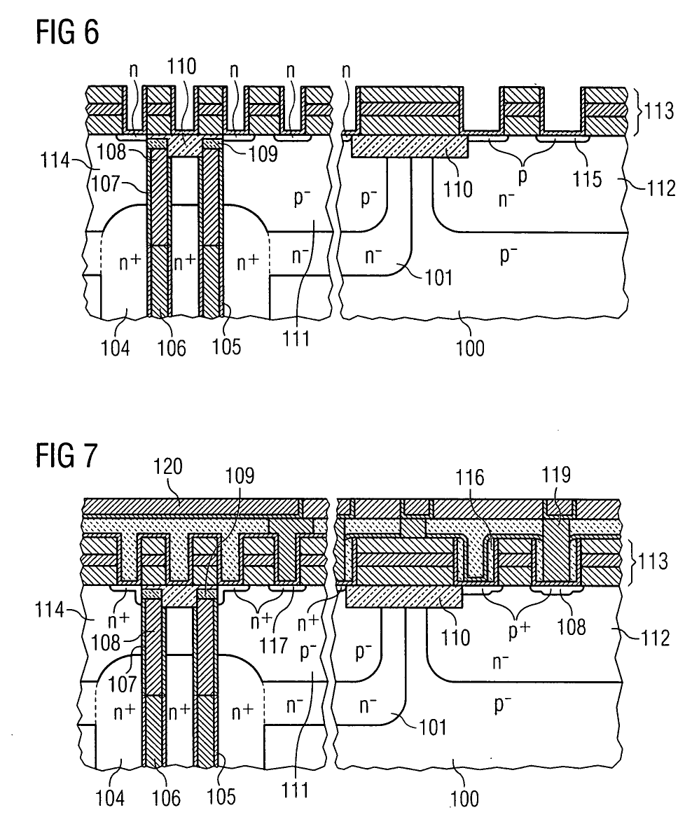

After the production of the gate electrode tracks 113, LDD zones 114 for the n-channel transistors may be defined with the aid of a lithography step and be doped by a subsequent ion implantation e.g. of arsenic. Analogously, the LDD zones 115 for the p-channel transistors are then defined with the aid of a lithography step and doped by ion implantation e.g. of boron. FIG. 6 shows a cross section through the silicon wafer after the formation of the LDD zones of the n- and p-channel transistors.

In a further process step, spacers 116 are then produced around the gate electrode tracks 113. Afterward, the highly doped regions of the source/drain electrode 117, 118 of the n-channel transistors and p-channel transistors are then formed with the aid of two successive ion implantations. In this case, arsenic, for example, is used as n⁺-type doping and boron, for example, is used as p⁺-type doping. In this case, the doping depth is chosen such that it lies above the dielectric intermediate layer 105 of the trench capacitors which comprises a low-temperature high-k dielectric.

The activation of the dopants is then performed with the aid of a laser annealing, a flash annealing or an SPER annealing. These short-time heat treatment methods for activating the dopants make it possible to delimit heating of the silicon wafer to the surface region in which the doping is introduced. This ensures that the temperatures of above 1000° C. that are required in this activation process do not damage the high-k dielectric layer 105 of the trench capacitors, which is thermally unstable above 800° C.

In the case of flash annealing, the procedure is generally such that the silicon wafer is heated to a first temperature of between 200° C. and 600° C., preferably between 400° C. and 500° C., by means of a first lamp. The desired temperature of above 1000° C. is then generated by a high-energy flash lamp, the flash lamp being active for between 1 and 100 msec, preferably 30 msec, and having a flash energy of 15 to 35 mJ/cm², preferably 25 to 29 mJ/cm².

In the case of laser annealing the short-time heat treatment is performed by means of local temperature coupling-in with the aid of a laser beam that scans the wafer surface.

In the case of the SPER method a recrystallization of the doping region is performed, heating being effected to a temperature of 600° C. to 800° C. for up to 1 min with a temperature rise of K/10 to K/150 sec, preferably greater than K/50 sec. It is preferred in this case for a temperature of 700° C. to be held for 5 sec.

The procedure according to the invention, in which only the semiconductor surface in the region of the doping implantation is heated to a great extent, makes it possible to achieve a sufficient dopant activation of the source/drain regions of the switching transistors without damaging the low-temperature high-k dielectric layers of the trench capacitors.

With a further process sequence, the source/drain regions of the switching transistors are then contact-connected and connected up to one another via interconnects. FIG. 7 shows a cross section through the silicon wafer after the contact-connection 119 and formation of the first metalization plane 120.

What is claimed is:

1. A method for fabricating a memory which is formed as an integrated circuit in a semiconductor substrate and comprises storage capacitors and switching transistors; comprising:
forming the storage capacitors in the semiconductor substrate in each case in a trench and having an outer electrode layer, which is formed around the trench, a dielectric intermediate layer, which is embodied on the trench wall and comprises a high-k dielectric that is unstable at high temperatures of above 800° C., and an inner electrode layer, with which the trench is essentially filled;
forming the switching transistors in the semiconductor substrate in each case in a surface region and having a first source/drain doping region, a second source/drain doping region and an intervening channel, which is separated from a gate electrode by an insulator layer;
embodying the dielectric intermediate layer of the storage capacitors in a manner spaced apart from the surface of the semiconductor substrate at least by a magnitude corresponding to the depth to which the source/drain doping regions of the switching transistors extend in the semiconductor substrate; and
using a short-time heat-treatment method being used for the thermal activation of the dopants in the source/drain doping zones of the switching transistors at temperatures of above 1000° C., during which method the thermal energy is coupled in from the wafer surface for a few microseconds to milliseconds.

2. The method as claimed in claim 1, wherein the dielectric intermediate layer of the storage capacitors being spaced apart from the surface of the semiconductor substrate by at least 200 nm.

3. The method as claimed in claim 1, wherein the activation of the dopants of the source/drain doping regions of the switching transistors in the semiconductor substrate being performed with the aid of one of the methods laser annealing, flash annealing and SPER annealing.

4. The method as claimed in claim 3, wherein in the case of flash annealing the semiconductor wafer being heated to a first temperature of between 200° C. and 600° C. by means of a first lamp and then a temperature of above 1000° C. being generated by a high-energy flash lamp, the flash lamp being active for between 1 and 100 msec and having a flash energy of 15 to 35 mJ/cm².

5. The method as claimed in claim 3, wherein in the case of flash annealing the semiconductor wafer being heated to a first temperature of between 400° C. and 500° C. by means of a first lamp and then a temperature of above 1000° C. being generated by a high-energy flash lamp, the flash lamp being active for 30 msec and having a flash energy of 25 to 29 mJ/cm².

6. The method as claimed in claim 3, wherein in the case of laser annealing the short-time heat treatment being performed by means of local temperature coupling-in with the aid of a laser beam that scans the wafer surface.

7. The method as claimed in claim 3, wherein in the case of the SPER method a recrystallization of the source/drain doping regions of the switching transistors being performed, heating being effected to a temperature of 600° C. to 800° C. for up to 1 min with a temperature rise of K/10 to K/150 sec.

8. The method as claimed in claim 3, wherein in the case of the SPER method a recrystallization of the source/drain doping regions of the switching transistors being performed, heating being effected with a temperature rise of greater than K/50 sec and a temperature of 700° C. being held for 5 sec.

9. A method for fabricating a memory which is formed as an integrated circuit in a semiconductor substrate and comprises storage capacitors and switching transistors, comprising:
forming the storage capacitor in the semiconductor substrate as a trench capacitor and the switching transistors being formed as field effect transistors;
forming a dielectric intermediate layer of the trench capacitors with a low-temperature high-k dielectric, the dielectric intermediate layer of the storage capacitors being embodied in a manner spaced apart from the surface of the semiconductor substrate at least by a magnitude corresponding to the depth to which the source/drain doping regions of the field effect transistors extend; and
using one of the methods laser annealing, flash annealing and SPER annealing for the thermal activation of the dopants in the source/drain doping zones of the switching transistors in the semiconductor substrate.

10. The method as claimed in claim 9, wherein in the case of flash annealing the semiconductor wafer being heated to a first temperature of between 200° C. and 600° C. by means of a first lamp and then a temperature of above 1000° C. being generated by a high-energy flash lamp, the flash lamp being active for between 1 and 100 msec and having a flash energy of 15 to 35 mJ/cm².

11. The method as claimed in claim 9, wherein in the case of flash annealing the semiconductor wafer being heated to a first temperature of between 400° C. and 500° C. by means of a first lamp and then a temperature of above 1000° C. being generated by a high-energy flash lamp, the flash lamp being active for 30 msec and having a flash energy of 25 to 29 mJ/cm².

12. The method as claimed in claim 9, wherein in the case of laser annealing the short-time heat treatment being performed by means of local temperature coupling-in with the aid of a laser beam that scans the wafer surface.

13. The method as claimed in claim 9, wherein in the case of the SPER method a recrystallization of the source/drain doping regions of the switching transistors being performed, heating being effected to a temperature of 600° C. to 800° C. for up to 1 min with a temperature rise of K/10 to K/150 sec.

14. The method as claimed in claim 9, wherein in the case of the SPER method a recrystallization of the source/drain doping regions of the switching transistors being performed, heating being effected with a temperature rise of greater than K/50 sec and a temperature of 700° C. being held for 5 sec.

15. A memory which is formed as an integrated circuit in a semiconductor substrate, comprising:
storage capacitors formed in the semiconductor substrate in each case in a trench and having an outer electrode layer, which is formed around the trench, a dielectric intermediate layer, which is embodied on the trench wall, and an inner electrode layer, with which the trench is essentially filled; and
switching transistors formed in the semiconductor substrate in each case in a surface region and having a first source/drain doping region, a second source/drain doping region and an intervening channel, which is separated from a gate electrode by an insulator layer, wherein
the dielectric intermediate layer of the storage capacitors comprising a low-temperature high-k dielectric,
the source/drain doping regions of the switching transistors extending to a depth of approximately 200 nm from the surface of the semiconductor substrate, and
the dielectric intermediate layer of the storage capacitors being spaced apart from the surface of the semiconductor substrate by at least 200 nm.

16. The memory as claimed in claim 15, the low-temperature high-k dielectric comprising at least one of the following materials: tantalum oxide, aluminum oxide, hafnium oxide, zirconium oxide, lanthanum oxide, yttrium oxide, an aluminum oxide compound with hafnium, zirconium or lanthanum, a silicate compound with hafnium, zirconium, lanthanum or yttrium.
